(19) United States
(12) Patent Application Publication
(10) Pub. No.: US 2011/0187360 A1
(43) Pub. Date: Aug. 4, 2011

(54) MRI SENSOR BASED ON THE HALL EFFECT FOR CRM IMD APPLICATIONS

(76) Inventors: Keith R. Maile, New Brighton, MN (US); Scot C. Boon, Lino Lakes, MN (US); Abhi V. Chavan, Maple Grove, MN (US)

(21) Appl. No.: 13/019,850

(22) Filed: Feb. 2, 2011

Related U.S. Application Data
(60) Provisional application No. 61/301,428, filed on Feb. 4, 2010.

(51) Int. Cl. G01R 33/07

(52) U.S. Cl. 324/251

(57) ABSTRACT

A method and device can include a Hall effect sensor, which can be formed as a portion of an integrated circuit of an implantable device and which can produce a non-linear current path such as to permit detecting a magnetic field parallel with the orientation of the Hall effect sensor of the implantable device.

### CLAIM OF PRIORITY

This application claims the benefit of priority under 35 U.S.C. § 119(e) to

Maile, U.S. Provisional Patent Application Ser. No. 61/301,428, entitled “MRI SENSOR BASED ON THE HALL EFFECT FOR CRM IMD APPLICATIONS,” filed on Feb. 4, 2010, (Attorney Docket No. 279.H7IPRV), which is hereby incorporated by reference herein in its entirety.

### BACKGROUND

An implantable medical device (IMD) can be used to monitor a physiological parameter or provide therapy, such as to elicit or inhibit a muscle contraction, or to provide neural stimulation, or for other therapeutic or diagnostic uses. An example of an IMD can include a cardiac rhythm management (CRM) device, can be configured to provide electrical stimulation to the heart such as to treat disorders of cardiac rhythm. Examples of CRM devices include, among other things, pacers, cardiac resynchronization devices, and implantable cardioverter/defibrillators (ICDs). CRM devices can use sensing capability in order to appropriately deliver stimulation to the heart. For example, pacers can be programmed to deliver bradycardia pacing in a synchronous mode in which paces can be inhibited or triggered by sensed intrinsic cardiac activity. The pacer can restore the heart to normal rhythm by delivering small electrical pacing pulses to the heart such as to elicit responsive contractions.

### OVERVIEW

In many instances, it may be beneficial to change the characteristics of the IMD without removing the device surgically. While this may be done telemetrically using a remote or local external programmer, in certain circumstances, no programmer may be available. Therefore, an IMD can include a magnetically triggered switch, such as to allow an IMD to change from one mode to another, such as by externally applying a permanent magnet.

However, an IMD may be exposed to other magnetic fields, such as from a magnetic resonance imaging (MRI) device, which can provide a strong static magnetic field, a time-varying gradient field, and a radio frequency field which includes RF pulses for producing the image. The static magnetic field can range from 0.2 Tesla to 5 Tesla. The time varying gradient field is used for spatial encoding, and has a frequency in the Kilohertz range. The RF field ranges from about 6 to 60 MHz.

An IMD may not automatically detect when an MR scan is being received. The MR magnetic field may affect operation of a CRM device, if not properly detected. For example, the MR static magnetic field may actuate the magnetically controlled switch of the CRM device. Thus, MR scans can be problematic for pacer or ICD patients such as by interfering with proper operation, causing overheating, or causing damage by a magnetic force.

In order to mitigate these issues, CRM devices can be reprogrammed to a non-sensing operating mode during an MR scan. However, as mentioned above, device reprogramming may involve calling a representative of the CRM manufacturer to re-program the device using a specialized external programmer for the CRM device. The representative may have to wait until the MR scan has been completed to again re-program the CRM device back to its previous operating state.

In an example, a Hall effect sensor may be in communication with or incorporated within an IMD, such as, for example, a CRM device, in order to detect an electromagnetic field and assist in the determination of an operation mode. A sufficiently large magnetic field can interfere with the delivery of electrostimulation pulses, such as by inadvertently placing a cardiac management device into one or more non-therapy or reduced-therapy modes, such as a test mode, a factory preset mode where therapy is disabled, a safety or fallback mode providing more limited therapy, or one or more other modes. If the magnetic fields are very large, for example, as with magnetic fields generated by a magnetic resonance imaging procedure, abnormally large electrical currents can flow in the circuit conductors, abnormally large physical forces can be experienced by circuits containing magnetic materials, or one or more other undesirable effects can occur. Such abnormally large currents can cause excessive internal heating to occur and can damage the internal components of the cardiac rhythm management device. Similarly, the abnormal large forces experienced by the circuits containing magnetic materials can result in temporary impairment or permanent damage to the cardiac rhythm management device. Detection of the electromagnetic field when operating a magnetic resonance machine may be useful to determine the operation mode of the implantable device such as the CRM.

In an example, a Hall effect sensor can be formed as a portion of an integrated circuit that can include a processor. The integrated Hall effect sensor can be used to sense the presence of a magnetic field and to provide a signal, such as for use in selecting an MR-compatible or other operating mode. In an example, the current path of a Hall effect sensor can be modified, such as to permit detecting a magnetic field parallel with the orientation of the Hall effect sensor formed as a portion of an integrated circuit of an implantable device—which can be the likely orientation of the magnetic field experienced for a typical pectorally-implanted CRM device in a patient lying supine in an MR seamier.

Example 1 describes subject matter that can use or include an apparatus comprising an implantable device, including a magnetic field detector configured to detect a magnetic field, the magnetic field detector comprising first Hall-effect sensor, the first Hall-effect sensor including first and second current terminals configured to provide a first current path therebetween for Hall-effect magnetic field sensing using first and second voltage sensing terminals transverse to the first current path wherein the first Hall-effect sensor includes a first permanent current barrier located between the first and second current terminals and configured such that the first current path is non-parallel with a surface of the first Hall-effect sensor.

In Example 2, the subject matter of Example 1 can optionally include a processor circuit, electrically coupled to the magnetic field detector, the processor capable of selecting an operating mode of the implantable device based on the magnetic field detected by the magnetic field detector.

In Example 3, the subject matter of any one of Examples 1 or 2 can optionally include the processor being configured to select a magnetic resonance (MR) compatible therapy mode when an MR magnetic field is detected.

In Example 4, the subject matter of any one of Examples 1-3 can optionally include a second Hall-effect sensor including third and fourth current terminals configured to provide a second current path therebetween for Hall-effect magnetic field sensing using third and fourth voltage sensing terminals located transverse to the second current path, wherein the first current path is non-parallel to the second current path.

In Example 5, the subject matter of any one of Examples 1-4 can optionally include the first current path of the first Hall-effect sensor being substantially perpendicular to the second current path of the second Hall-effect sensor.

In Example 6, the subject matter of any one of Examples 1-5 can optionally include the first permanent current barrier between the first and second current terminals of the first Hall-effect sensor comprising a counterdoped diffusion.

In Example 7, the subject matter of any one of Examples 1-6 can optionally include the first permanent current barrier between the first and second current terminals including a deep reactive ion-etched (DRIE) current barrier.

In Example 8, the subject matter of any one of Examples 1-7 can optionally include the first permanent current barrier between the first and second current terminals comprises a shallow trench isolation comprising a depth of less than 10 μm.

In Example 9, the subject matter of any one of Examples 1-8 can optionally include the first permanent current barrier between the first and second current terminals comprises a deep trench isolation comprising a depth of greater than 5.0 μm.

In Example 10, the subject matter of any one of Examples 1-9 can optionally include the magnetic field sensor comprising a third Hall-effect sensor including fifth and sixth current terminals configured to provide a third current path therebetween for Hall-effect magnetic field sensing using fifth and sixth voltage sensing terminals transverse to the third current path, wherein the third Hall-effect sensor includes a second permanent current barrier located between the fifth and sixth current terminals, and wherein the first current path is non-parallel to the second current path and the third current path is non-parallel to the first and second current paths.

In Example 11, the subject matter of any one of Examples 1-10 can optionally include the first permanent current barrier being located in a range between about 0.1 μm and about 1000 μm away from the first current terminal.

In Example 12, the subject matter of any one of Examples 1-11 can optionally include a depth of the first permanent current barrier being a value between about 0.01 μm and about 100 μm.

In Example 13, the subject matter of any one of Examples 1-12 can optionally include the first permanent current barrier being configured such that the first current path includes a portion that is angled at an angle value that is between about 0.05° and about 45° in relation to a surface of the first Hall-effect sensor.

In Example 14, the subject matter of any one of Examples 1-13 can optionally include the first Hall-effect sensor and second Hall-effect sensor are part of the same integrated circuit.

In Example 15, the subject matter of any one of Examples 1-14 can optionally include the first permanent current barrier between the first and second current terminals of the first Hall-effect sensor comprising: a counter-doped well region; and a diffusion region, adjacent to, shallower than, and of opposite doping as the counter-doped well region.

Example 16 describes subject matter that can include, or that can be combined with the subject matter of any one of Examples 1-15 to optionally include detecting a magnetic field using a magnetic field detector of an implantable device, wherein the detecting comprises: producing a first current path non-parallel to the surface of an integrated circuit of the magnetic field detector caused by a first permanent current barrier distorting the first current path; and sensing the magnetic field using a response voltage that is transverse to the first current path.

In Example 17, the subject matter of any one of Examples 1-16 can optionally include selecting an operating mode of the implantable device based on the detected magnetic field, using a processor electrically coupled to implantable device.

In Example 18, the subject matter of any one of Examples 1-17 can optionally include detecting that the magnetic field is a magnetic resonance (MR) magnetic field; and selecting an MR-compatible mode of the implantable device when the MR magnetic field is detected.

In Example 19, the subject matter of any one of Examples 1-18 can optionally include producing a second current path, wherein the second current path is non-parallel to the first current path caused by a second permanent current barrier distorting the second current path.

In Example 20, the subject matter of any one of Examples 1-19 can optionally include producing the first current path comprises producing the first current path to be non-parallel to a surface of a first Hall effect sensor.

These examples can be combined in any permutation or combination. This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows an example of a portion of an implantable cardiac rhythm management device.

FIG. 2A shows a planar view of an example of a Hall effect sensor for an implantable device such as the cardiac rhythm management device of FIG. 1,

FIG. 2B shows an example of a cross-sectional view of the Hall effect sensor of FIG. 2A.

FIG. 3A shows a planar view of an example of a Hall effect sensor for an implantable device.

FIG. 3B shows an example of a cross-sectional view of the Hall effect sensor of FIG. 3A for an implantable medical device.

FIG. 4A shows a planar view of an example of a Hall effect sensor for an implantable device with quadrilateral geometry.

FIG. 4B, shows a cross sectional view of an example of a Hall effect sensor for an implantable medical device.

FIG. 5 shows an example of a method for detecting a magnetic field using a magnetic field detector of an implantable medical device.

FIG. 6 shows a planar view of an example of a magnetic field detector of an implantable device with first and second Hall effect sensors.

### DETAILED DESCRIPTION

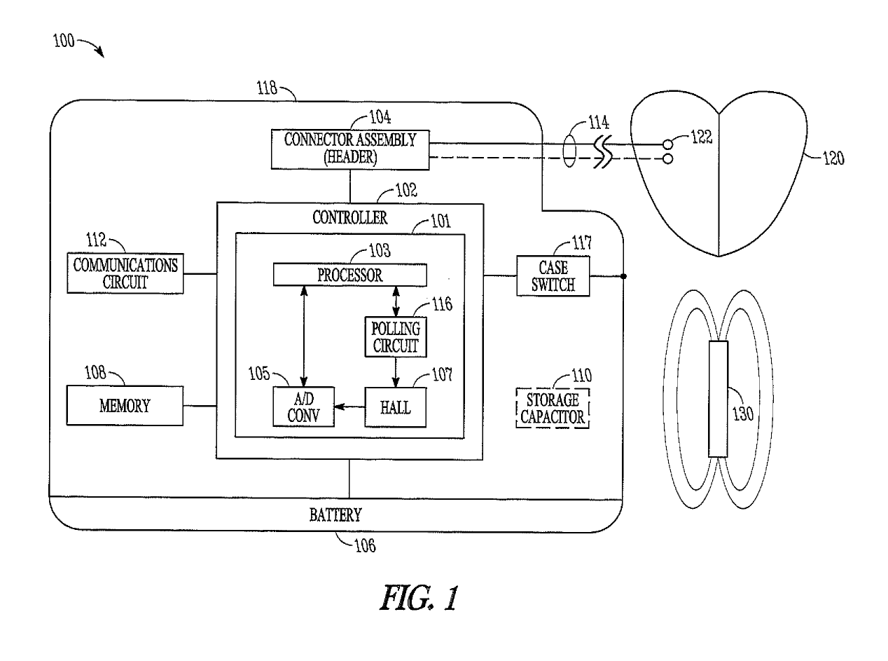

FIG. 1 shows an example of a portion of an implantable cardiac rhythm management device 100. In an example, the cardiac rhythm management device 100 can deliver electrostimulation to, or sense spontaneous intrinsic or evoked depolarization from, a desired portion of a heart 120. In an example, the cardiac rhythm management device 100 can include a controller circuit 102, a connector assembly 104, a battery 106, a memory unit 108, communications circuitry 112, a case switch 117, and an energy storage capacitor 110 located within casing 118. In an example, the controller 102 can include an integrated circuit module 101 with a processor circuit 103, an analog-digital circuit 105, a polling circuit 116, and a Hall effect sensor 107. In an example, electrostimulation pulses can be derived from the energy storage capacitor 110 and delivered to one or more heart chambers, such as via one or more electrodes 122, which can be associated with one or more leads 114. In an example, the polling circuit 116 can be used to provide an excitation current or an excitation voltage signal to the Hall effect sensor 107. In an example, the polling circuit 116 can include a timing circuit or can be configured to receive one or more timing control signals from the processor 103. As explained below, the Hall effect sensor 107 can be used to sense the presence or the strength of a magnetic field, such as originating from an external magnetic device, such as a magnetic device 130 (e.g., a permanent magnet, an electromagnet, a static or dynamic magnetic field from one or more pieces of diagnostic medical apparatus such as a magnetic resonance imaging (MRI) scanner, or one or more other sources of the magnetic field). In an example, the magnetic device 130 can include a magnet intentionally placed near the cardiac rhythm management device 100 by a user, or another device capable of generating a magnetic field of sufficient strength to trigger a change from the normal ambulatory operating mode, such as by placing the cardiac rhythm management device in a battery status test mode, a mode configured to abort therapy delivery, a mode to trigger storage of electrograms containing physiologic information derived from one or more tissue sites, a mode to trigger one or more research features, a mode to increase or decrease therapy, or one or more other operating modes. In an example, a signal generated by the Hall effect sensor 107 in the presence of a magnetic field can also be used by the processor 103 to select between one or more pacing, defibrillation, or one or other operating modes. In an example, such magnetic-field-triggered modes can be programmed into a memory unit 108. In an example, the integrated circuit module 101 can include a semiconductor memory, such as a flash memory, NMOS, static random access memory (SRAM), dynamic random access memory (DRAM), erasable programmable read-only memory (EPROM), electrically erasable programmable read-only memory (EEPROM), or one or more other forms of semiconductor memory such as to store instructions or data, such as associated with a cardiac therapy.

In an example, one or more of the processor 103, the analog-digital circuit 105, the polling circuit 116, or the Hall effect sensor 107 can be formed monolithically and integrated together on a single commonly shared substrate, such as silicon, silicon-on-insulator, silicon-on-sapphire, silicon carbide, silicon germanium, silicon germanium carbide, gallium arsenide, gallium nitride, indium phosphide, diamond, or one or more other substrate materials included as a portion, part, or component of a commonly shared integrated circuit or a commonly shared integrated circuit package. In an example, one or more of the processor 103, the analog-digital circuit 105, the polling circuit 116, or the Hall effect sensor 107 can be included as a portion, part, or component of an integrated circuit package (e.g., a plastic-encapsulated ball grid array (BGA), flip-chip, land grid array (LGA), tape-automated bonding (TAB), or one or more other types of an integrated circuit package).

In an example, a portion of the integrated circuit module 101 can include circuits formed of different materials. For example, the Hall effect sensor 107 can be formed as a separate die and attached to the integrated circuit module 101 via solder bump mounting technology, flip-chip technology, or one or more other packaging, mounting, or assembly techniques. The Hall effect sensor 107 can also be formed directly on the integrated circuit module 101 by a semiconductor or other manufacturing process, such as chemical vapor deposition. Thus, the Hall effect sensor 107 can include a semiconductor material that is different than the semiconductor material used for forming the processor 103, the analog-digital circuit 105, or the polling circuit 116, or one or more other circuits included as a portion of the integrated circuit module 101 or one or more other modules. In certain examples, one or more materials with higher Hall mobilities, such as indium antimonide, gallium antimonide, or one or more other materials can be selected to enhance sensitivity of the Hall effect sensor 107 to a magnetic field. In an example, epitaxial silicon wafers can be used to form the Hall effect sensor. The Hall effect sensor 107 can be formed as a heterostnicture device including adjoining layers having one or more bandgap energies different from an adjoining layer to confine current flow. Layers with different bandgap energies can be obtained, for example, with III-VI and compound semiconductors, such as aluminum gallium arsenide-gallium arsenide, indium phosphide-indium gallium arsenide, or one or more other compound semiconductors.

The cardiac rhythm management device 100 shown is for ease in understanding the examples described, and is not meant to limit device 100 to the particular configuration illustrated. For example, the communications circuit 112 and the memory 108 can be formed monolithically with the processor 103 as a portion of the integrated circuit module 101, and can be included in the cardiac rhythm management device 100 along with one or more other circuits or modules. In an example, the timing circuit can be included as a portion of the processor 103 or the analog-to-digital circuit 105.

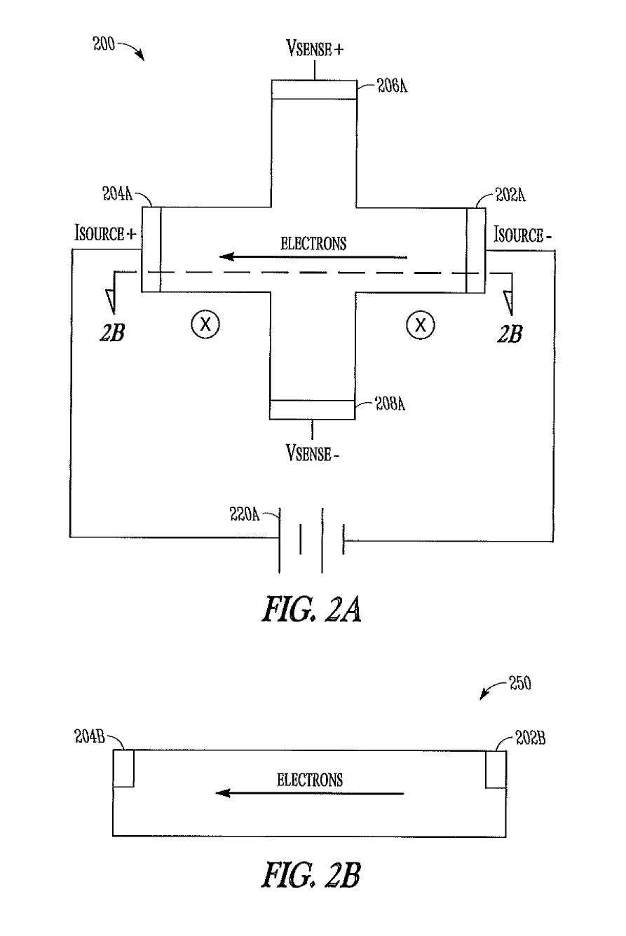

FIG. 2A shows an example of a planar view of an example of a Hall effect sensor 200 for an implantable cardiac device such as the cardiac rhythm management device 100 of FIG. 1, in an example. Illustrated in the example of FIG. 2A, the Hall effect sensor 200 can include a first current terminal 202A, a second current terminal 204A with a current path provided generally from the first current terminal 202A to the second current terminal 204A, as depicted by the arrow between the two terminals. The current path can be produced by a voltage source 220A. A first voltage sensing terminal 206A and a second voltage sensing terminals 208A can be disposed transverse to the current path so that the Hall effect sensor 200 can measure a magnetic field using a magnetic-field responsive output voltage between the first voltage sensing terminal 206A and the second voltage sensing terminal 208A. The dashed line labeled ‘B’ illustrates a dividing line for taking the cross-sectional view 250 as depicted in FIG. 2B.

FIG. 2B shows an example of a cross-sectional view 250 of the example of the Hall effect sensor 200 of FIG. 2A, Illustrated in the example of FIG. 2B, the Hall effect sensor 250 can include a current path designated by the arrow between a first current terminal 202B (corresponding with first current terminal 202A of FIG. 2A) and a second current terminal 204B (corresponding with the second terminal 204A of FIG. 2A), In the example shown, the current path can be substantially parallel to the surface of the Hall effect sensor. In an example, the Hall effect sensor can be oriented parallel with the flat major surface of the entire implantable cardiac device 100 of FIG. 1. In such an example, the current path can be parallel to the flat major surface of implantable device 100.

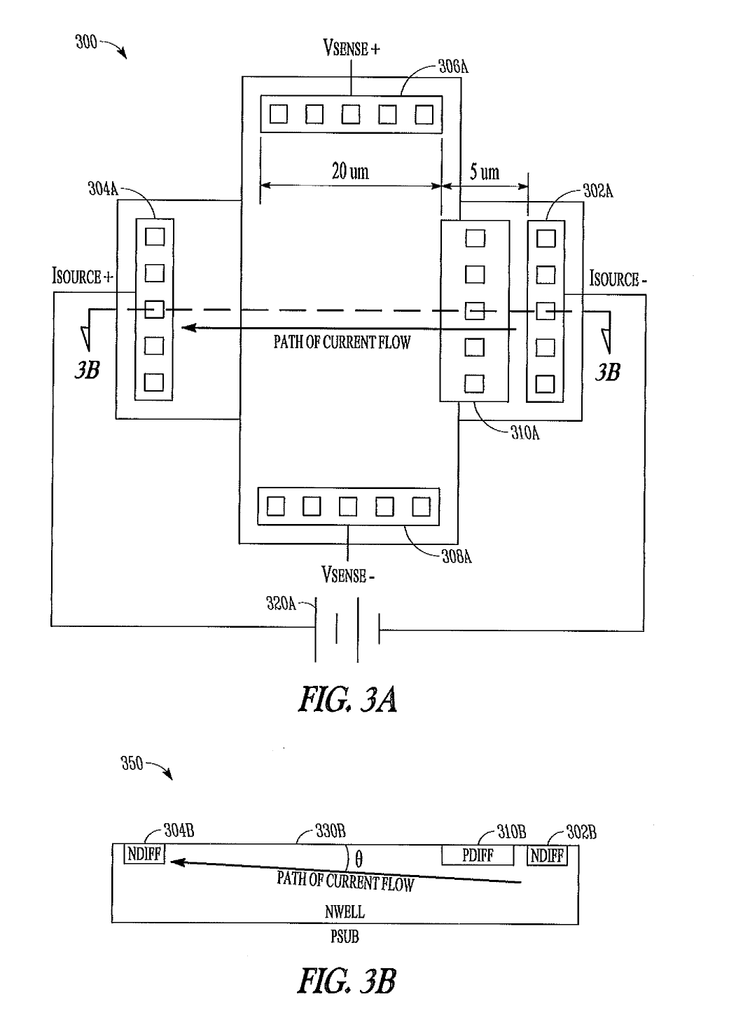

FIG. 3A shows an example of a planar view of an example of a Hall effect sensor 300 for an implantable device, such as the cardiac rhythm management device 100 of FIG. 1. In the example of FIG. 3A, in addition to the a first current terminal 302A and a second current terminal 304A, the Hall effect sensor 300 can include a permanent current barrier 310A, which can be disposed between the first current terminal 302A and the second current terminal 304A. In an operative example, a voltage source 320A can produce a current path, which can travel from the first current terminal 302A to the second current terminal 304A, as depicted by the arrow between the two terminals. With the first current barrier 310A disposed between the first and second terminals 302A and 304A, the current path travels at an angle to the surface of the Hall effect sensor 300 to get around the barrier 310A, such as discussed with reference to FIG. 3B. A first voltage sensing terminal 306A and a second voltage sensing terminal 308A can be disposed transverse to the current path for the Hall effect sensor 300 to measure a magnetic field by determining the variability of an output voltage between the first voltage sensing terminal 306A and the second voltage sensing terminal 308A.

In the example of FIG. 3A, the Hall effect sensor 300 can have a cross geometry with a first current terminal 302A disposed across from a second current terminal 304A, and the first voltage sensing terminal 306A across from ₜhe second voltage sensing terminal 308A. In an example, the voltage sensing terminals 306A and 308A can have a spacing of 30 μm, and the first and second current terminals 302A and 304A can have a spacing of about 30 μm, and a width in a range of about 20 μm. In an example, the length and width of the first current terminal 302A can differ from the length and width of the second current terminal 304A. In an example, the length of the permanent current barrier 310A can differ from the first current terminal 302A. In an example, the width of the permanent current barrier 310A can differ from the width of the first current terminal 302A, for example, the width of the permanent current barrier 310A can be 25 μm. In an example, the depth of the permanent current barrier 310A can differ from the depth of the first current terminal 302A. With the depth of the first current barrier 310A greater than or equal to the depth of the first current terminal 302A (and the width of the permanent current barrier 310A greater than or equal to the width of the first current terminal 302A), the current path from the first current terminal 302A to the second current terminal 302B can be non-parallel to the top surface of the Hall effect sensor 300. In an example, the depth of the permanent current barrier 310A can be 2 μm. These dimensions are provided by way of example. Dimensions may range from a fraction of a micron up to thousands of microns.

In an example, the first current terminal 302A can be adjacent to and substantially parallel with the permanent current barrier 310A. In an example, there can be a space between the first current terminal 302A and the permanent current barrier 310A, such as a space of 1 μm, or can be a distance in a range of about 0.1 μm to about 1000 μm. In an example, the permanent current barrier 310A can be formed in a shape conducive to produce a current flow that is non-parallel to a surface of the Hall effect sensor 300 and need not be limited to specific dimensions.

FIG. 3B shows an example of a cross-sectional view 350 of an example of the Hall effect sensor 300 of FIG. 3A for an implantable medical device. In the example of FIG. 3B, the Hall effect sensor 300 can include a current path designated by the arrow between a first current terminal 302B (corresponding with first current terminal 302A of FIG. 3A) and a second current terminal 304B (corresponding with the second terminal 304A of FIG. 3A). A permanent current barrier 310B can be disposed between the first current terminal 302B and the second terminal 304B, such as to create a current path between the first and second current terminals 302B and 304B that is non-parallel (e.g., at a non-zero angle 0) to the top surface 330B of the Hall effect sensor 300.

In FIG. 3B, the depth of the permanent current barrier 310B can be greater than or equal to the depth of the first current terminal 302B. In an example, the first current barrier 310B can be a p-type diffusion and the first and second current terminals 302B and 304B can be an n-type diffusion formed in an n-type well on a p-type substrate. Terminals 302B and 304B provide the ohmic contact to the n-well, which can produce the Hall effect sensor. In an example, terminals 302B and 304B can be of the same diffusion type (e.g., n-type). It is to be noted that wells can be used for terminals 302B and 304B, in an example, when the Hall effect sensor is formed by a deeper well.

The current path angle θ can be modified by one or more characteristics of the Hall effect sensor 300 or any combination characteristics. In an example, the proximity of the permanent current barrier 310B to the first current terminal 302B can be adjusted, as desired, such as to alter the current path and the path angle θ. For example, a spacing of 25 μm between the permanent current barrier 310B and the second current terminal 304B with a depth of about 5 μm, can produce a current path angle θ of about 11°. Reducing the spacing between the permanent current barrier 310B and the second current terminal 304B to 10 μm produces a current path angle θ of about 27°.

In an example, the depth of the permanent current barrier 310B can be adjusted, as desired, such as to alter the path angle θ of the current path. For example, a spacing of 25 μm between the permanent current barrier 310B and the second current terminal 304B, with a depth of 3 nm of the permanent current barrier 310B can produce a current path angle θ of about 7°. In an example, a Hall effect device with a spacing of 50 μm and a 0.3 μm deep p+ (P diffusion) would produce an angle θ of 0.34°. In examples, the path angle θ of the current path can be in the range of about 0.05° to about 45°.

In an example, the form of the permanent current barrier can alter the path angle θ. For example, the permanent current barrier 310B can include a deep trench permanent current barrier, a shallow trench permanent current barrier, a deep reactive ion etched permanent current barrier, or a counterdoped diffusion permanent current barrier, any of which can be used to produce the desired current path angle θ.

In examples, an n-type diffusion (n+) permanent current barrier can have depths in a range of about 0.1 μm to about 1 μm, and a p-type diffusion (p+) permanent current barrier can have a depth in a range of about 0.1 to about 1 μm. In an example, when using n-type or p-type permanent current barriers, the typical range of the depth can be from about 0.1 μm to about 0.5 μm. In examples, n-well and p well current barriers can have depths in the range of about 1 μm to about 10 μm. In examples, a deep trench permanent current barrier can have a depth of about 5 μm to about 50 μm and can typically have a depth of about 10 μm. In examples, a shallow trench permanent current barrier can have a depth of about 0.1 μm to about 10 μm and can typically have a depth of about 0.1 μm to about 0.5 μm. In examples, trenches can be available in high-end IC processes (e.g., IBM 7HP). In an example, the current path angle θ of the current path can be produced ratiometrically with the depth of the first current barrier 310B and the distance between the first current barrier 310B the second current source 304B. In an example, the magnetic field Bₒ can be substantially parallel to the flat major surface of an IMD, and hence substantially to a top surface of a Hall effect sensor 300, when the patient with the IMD is lying supine within a MRI scanner. Under such circumstances, providing the non-parallel current path described herein can help allow the Hall effect sensor 300 to detect a magnetic field (e.g., with Bₒ parallel with the top surface 330B of the Hall effect sensor 300). A relatively small angle θ can be useful for the Hall effect sensor 300, since the magnetic field Bₒ produced by an MRI device can be very strong.

In an example, the Hall effect sensor 300 can be incorporated in an implantable device, such as a cardiac rhythm management device, and communicatively coupled to a processor. In an example, upon detecting a MR magnetic field, the processor can be used to estimate the magnetic field strength (e.g., its magnitude). In an example, the magnetic field strength can be derived from a digital signal provided by a digital-to-analog (D/A) circuit. The magnetic field strength can be compared, such as by the processor, to one or more programmable thresholds or windows, in an example. The result of the comparison can be used, in an example, to select an operating mode of the cardiac rhythm management device, In an example, a polling circuit can be communicatively coupled to the Hall effect sensor, such as to apply a voltage, current, or other signal to the Hall effect sensor. In an example, an analog-to-digital (AID) converter can be configured to receive one or more voltage, current, or other signals from the Hall effect sensor, such as in response to one or more signals applied by the polling circuit, and to convert the received signal to a digital signal. In an example, the A/D converter can provide a 12-bit voltage signal to the processor, such as for determining the magnetic field strength.

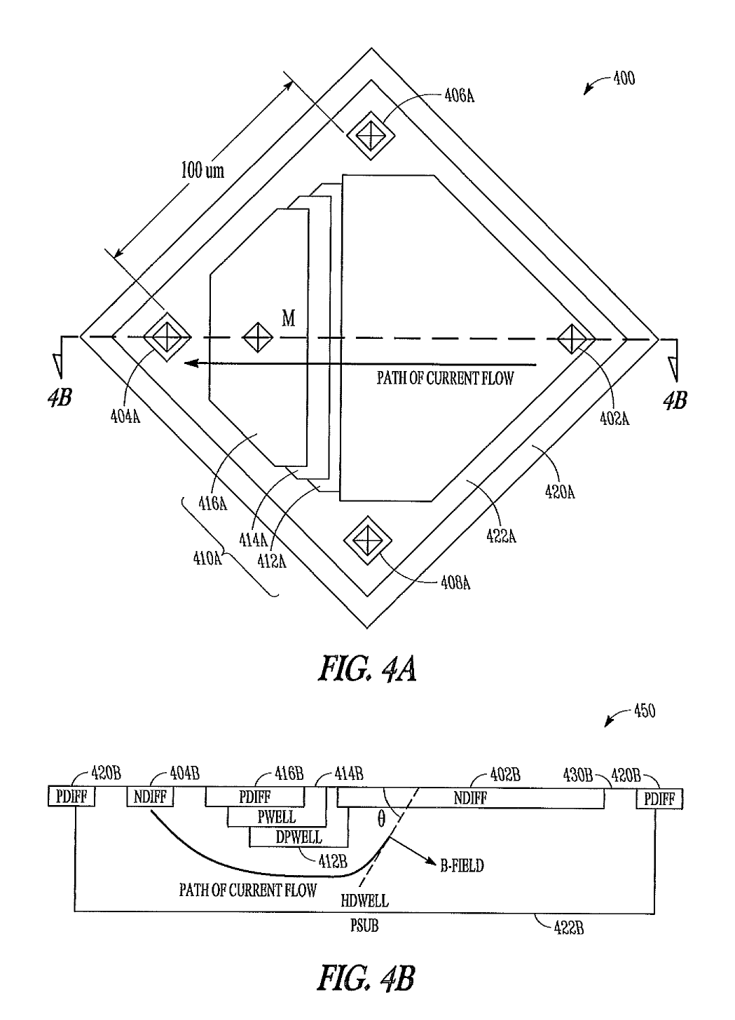

FIG. 4A shows an example of a planar view of an example of a Hall effect sensor 400 with a quadrilateral geometry, such as for an implantable device. In the example, a first current terminal 402A can be located diagonally across from a second current terminal 404A. A current source can be provided to produce a current between the first and second current terminals 402A and 404A. As designated by the arrow, in an example, the current path can flow from the first current terminal 402A toward the second terminal 404A. From the planar view of FIG. 4A, the current path appears parallel to the surface. In FIG, 4A, the dashed line ‘B’ demarks a line along which the cross-sectional view of FIG. 4B is taken, which, as discussed below, shows a non-parallel current path, at least a portion of which is non-parallel to a top surface of the Hall effect sensor 400.

In an example, the current path can be modified by a permanent current barrier 410A located between the first and second current terminals 402A and 404A such that the current path is non-parallel to a surface of the Hall effect sensor, such as described below with reference to FIG. 4B. In an example, the current barrier 410A can be constructed of a single material or a single doped region. In an example, the current barrier 410A can be formed by a plurality of materials or doped regions. In either case, the current barrier 410A can help to produce a current path that is non-parallel to the surface of the Hall effect sensor 400.

In an example, the permanent current barrier 410A can be constructed of three structures: a first structure 412A, a second structure 414A and a third structure 416A. In an example, the first structure 412A can be any one of the following: a deep reactive ion etched well, a deep trench isolation p-well, or the like. In an example, the second structure 414A can be a p-well and the third structure can be a p-diffusion. The first, second, and third structures 412A, 414A, 416A may be formed by these or other semiconductor processing methods. In an example, the three structures 412A, 414A, and 416A can provide a steep incline in a direction from the first current terminal 402A to the second current terminal 404A, such as to guide the current flow at an angle θ with respect to the top surface of the Hall effect sensor 400, in the vicinity of the transverse sensing terminals 406A and 408A. The current path angle can be determined by the diffusion or trench profile of structure 412A. Furthermore, the presence of shallow diffusion extending from the first terminal 402A in the vicinity of 412A can help with forming the steep incline.

In an example, the current path angle θ can vary across the current path in relation to the top surface 430B when traveling across the structures 412B, 414B and 416B, such as, to create a path that is non-parallel to the surface 430B. In an example, the current path angle θ of the current path can be produced ratiometrically with the depth of the permanent current barrier 410E and varying depths and number of structures.

In an example, fewer or greater number of structures can be used to form the permanent current barrier 410A of the Hall effect sensor 400. For example, the permanent current barrier 410A can include one or any combination of a deep trench permanent current barrier, a shallow trench permanent current barrier, a deep reactive ion etched permanent current barrier, or a counterdoped diffusion permanent current barrier, any of which can be used to produce a current path angle θ with respect to a top surface of the Hall effect sensor 400 in the current path between the first current terminal 402A and the second current terminal 404A. In an example, the first and second current terminals 402A and 404A can be formed using first and second n-diffusions, respectively. In an example, the first current terminal 402A can be formed in a first n-diffusion extending approximately from a diagonal defining half of the quadrilateral geometry of the Hall effect sensor 400 so as to encompass an area that can be nearly equivalent to a diagonal half of the Hall effect sensor 400. In an example, the n-diffusion can be formed in a right angle aligned with a contact at the first current terminal 402A, such as depicted in FIG. 4A.

In an example, a first voltage sensing terminal 406A and a second voltage sensing terminal 408A can be located transversely to the current flow path and diagonally across the Hall effect sensor 400 from each other. The first and second voltage sensing terminals 406A and 408A can be used to detect a change in response voltage caused by a magnetic field. In an example, the sensing terminals 406A and 408A can be communicatively coupled to a polling circuit that can be configured to receive one or more such response signals, and an A/D circuit can be configured to convert the received signals to digital form. In an example, the AID circuit can provide the digitized signal to a processor, which can be configured for estimating the magnetic field strength derived from the signal, such as by measuring its amplitude. In an example, the processor can then select an operating mode, such as from one or more programmable modes, using information based on the estimated magnetic field strength.

In an example, the spacing between the first current terminal 402A and the second current terminal 404A can be in the range of about 0.1 μm to about 1000 μm, while the spacing between one of the current terminals 402A and 404A and one of the two voltage sensing terminal 406A and 408A can be in the range of 0.1 to 1000 μm. In an example, each of the current terminals 402A and 404A can be equidistant from each of the first and second voltage sensing terminals 406A and 408A. In an example, the Hall effect sensor 400 can be formed in a square geometry, such as with the first and second current terminals 402A and 404A located diagonally across from each other along a first diagonal, while the first and second voltage sensing terminals 406A and 408A can be located diagonally across from each other along a second diagonal. In an example, the first and second current terminals 402A and 404A and the first and second voltage sensing terminals 406A and 408A can be located substantially in the corners of a square geometry Hall effect sensor 400.

In examples, the width and length of the cross geometry can be in the range of about 1 μm to about 1000 μm. In examples, the width of the cross can be longer or shorter than the length or vice-versa.

In the example of FIG. 4A and 4B, the Hall effect sensor 400 can comprise a deep well. In an example, the first and second current terminals 402A and 404A can include contacts to respective n-type diffusions, the first and second voltage detecting terminals 406A and 408A can also include contacts to respective n-type diffusions, the current barrier 410B can include one or more p-type well or other diffusions, all of which can all be formed in an n-type deep well diffusion 422B formed in a p-type substrate. In an example, the first and second current terminals 402A and 404A can include contacts to respective p-type diffusions, the first and second voltage detecting terminals 406A and 408A can also include contacts to respective p-type diffusions, the current barrier 410B can include one or more n-type well or other diffusions, all of which can all be formed in an p-type deep well diffusion 422B formed in a n-type substrate. FIG. 4B shows an example of a cross-sectional view 450 taken along a ‘B-B’ cutline of an example of the Hall effect sensor 400 of FIG, 4A, such as for an implantable medical device. In the example of FIG. 4B, the Hall effect sensor 400 can produce a current path for use in detecting a magnetic field using a transverse response voltage. In an example, the current path extends from an n-diffusion of the first current terminal 402B to an n-diffusion of the second current terminal 404B. In. an example, at least a portion of the current path is non-parallel with a surface of the Hall effect sensor 400. In an example, the current path can be substantially perpendicular to a top surface of the Hall effect sensor in a region near the transverse line between the detecting terminals 406A and 408A.

In an example, the direction or angle θ of the current path (e.g., electron flow) can be modified such as by varying the depth or construction of the current barrier 410B. In an example, the Hall effect sensor 400 can be used to detect a magnetic field produced by a magnetic resonance imaging machine. In an example, the Hall effect sensor 400 can be incorporated in an implantable device, such as an implantable cardiac rhythm management device, and placed within a patient. In some orientations, such as when the patient is lying supine inside of an MRI scanner, the magnetic field Bₒ produced by the MRI scanner may be parallel to the surface of the Hall effect sensor 400, and therefore might not be detected by a current path running parallel with the surface of the Hall effect sensor. However, using a current path that is configured to be non-parallel to the surface, such as described herein, the Hall effect sensor 400 can detect a magnetic field even when the magnetic field is parallel to the surface of the Hall effect sensor 400.

In an example, the current path can be modified such as by the varying one or more characteristics of the current barrier 410B, one or more characteristics of the first, second, or third structures 412B, 414B, 416B, or one or more characteristics of the first or second current terminals 402B and 404B. For example, the depth of the first structure 412B can be constructed significantly deeper than that of the second structure 414B, such as to increase an angle θ of the current path. In an example, adjusting the length or displacement between the n-diffusion of the first current terminal 402B, the n-diffusion of the second current terminal 404B, or any one of the structures 412B, 4I4B, 416B can modify the current path angle θ. In an example, the proximity of current barrier 41013 to the first current terminal 402B can be varied to produce a different current path angle θ although structure 412B provides the most vertical angle. The staircase profile of 410B at the terminal 404B side produces a more shallow angle to minimize the effect of this part of the current path on the detected level at terminals 406A and 408A. The signal provided between the first and second current terminals 402B and 404B can be specified to produce (e.g., in conjunction with the structures 412B, 414B, and 416B of the current barrier 410B) a current path angle θ that is substantially perpendicular to a surface of the Hall effect sensor 400 at a location where the current path is leaving the diffusion associated with the first current terminal 402B. The current path can then bend to travel at an angle from the perpendicular direction toward the second current terminal 404B. In an example in which a strong magnetic field is present parallel formed to the surface of the device, a very small current path angle θ can help to detect the strong magnetic field in such direction.

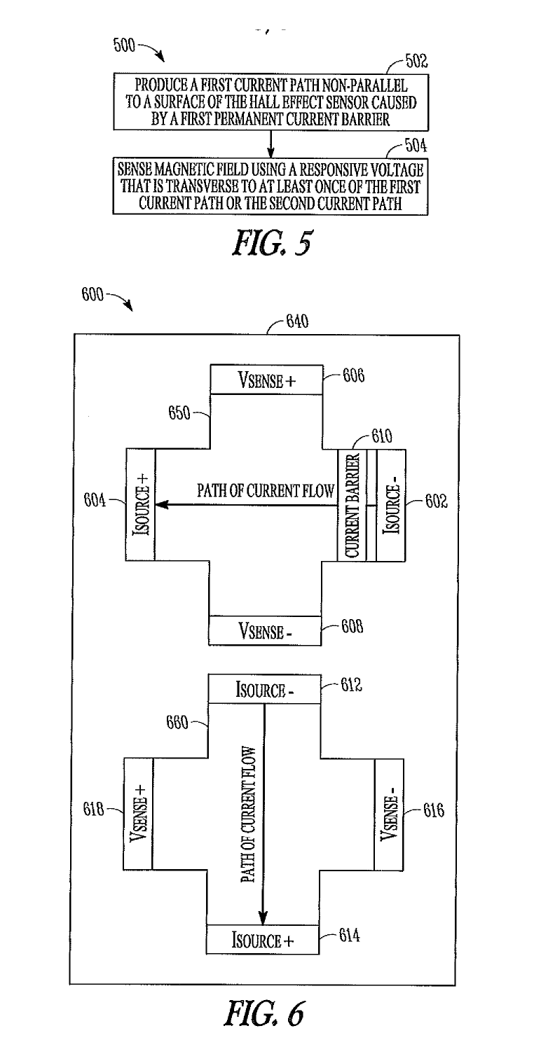

FIG. 5 shows an example of a method 500 such as for detecting a magnetic field using a magnetic field detector of an implantable medical device. At 502, a first current path non-parallel to a surface of the Hall effect sensor can be produced, such as caused by a permanent current barrier. At 504, a magnetic field can be sensed using a response voltage that is transverse to at least one of the current path or the second current path.

In an example, the method 500 can include selecting an operating mode of the implantable device, such as in response to detecting the magnetic field through use of a processor coupled to the implantable device. In an example, the method 500 can be used to determine whether the detected magnetic field is a magnetic resonance magnetic field, such as based on the detected field-strength, and can include selecting an MR-compatible mode of the implantable device when the MR magnetic field is detected. In an example, the method 500 can be used to produce a second current path that is non-parallel to the first current path. A second current barrier can be used to distort the second current path, such as to make it non-parallel to the first current paths. In an example, the second current path can be non-parallel to the surface of a first Hall effect sensor. In an example, the method 500 can include using, as the permanent current barrier, at least one of a deep trench permanent current barrier, a shallow trench current barrier, a deep reactive ion etched permanent current barrier, or a counterdoped diffusion permanent current barrier.

FIG. 6 shows a planar view 600 of an example of a magnetic field detector 640 of an implantable device with first and second Hall effect sensors 650 and 660. In the example, the first and second Hall effect sensors 650 and 660 have non-parallel current paths and can be a portion of the same magnetic field detector 640 as depicted in FIG. 6. The first Hall effect sensor 650 can have a cross geometry and can include a first current terminal 602 disposed across from a second current terminal 604 with a first current path provided generally from the first current terminal 602 to the second current terminal 604, as depicted by the arrow between the two terminals. The first Hall effect sensor 600 can include a permanent current barrier 610 which can be disposed between the first current terminal 602 and the second current terminal 604 and the first current path travels at an angle to the surface of the Hall effect sensor 650 to get around the barrier 610. A first voltage sensing terminal 606 and a second voltage sensing terminal 608 can be disposed transverse to the current path for the Hall effect sensor 650 to measure a magnetic field by determining the variability of an output voltage between the first voltage sensing terminal 606 and the second voltage sensing terminal 608.

In an example, the second Hall effect sensor 660 can also have a cross geometry and can include a third current terminal 612 and a fourth current terminal 614 with a second current path provided generally from the first current terminal 612 to the second current terminal 614, as depicted by the arrow between the two terminals. A first voltage sensing terminal 606 and a second voltage sensing terminal 608 can be disposed transverse to the current path for the Hall effect sensor 650 to measure a magnetic field by determining the variability of an output voltage between the first voltage sensing terminal 606 and the second voltage sensing terminal 608. In an example, the second Hall effect sensor 660 can be coplanar with the first Hall effect sensor 650 and can have an orientation different from the first Hall effect sensor. In an example, the second current path of the second Hall effect sensor 660 can be at an angle in relation to the first current path of the first Hall effect sensor 650 and the first current path and the second current path can have non-coplanar and non-parallel paths. In an example, the second Hall effect sensor can have an orientation of 90° in relation to the orientation of the first Hall effect sensor.

### Additional Notes

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples hi which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

1. An apparatus comprising:
an implantable device, including:
a magnetic field detector configured to detect a magnetic field, the magnetic field detector comprising first Hall-effect sensor, the first Hall-effect sensor including first and second current terminals configured to provide a first current path therebetween for Hall-effect magnetic field sensing using first and second voltage sensing terminals transverse to the first current path; and
wherein the first Hall-effect sensor includes a first permanent current barrier located between the first and second current terminals and configured such that the first current path is non-parallel with a surface of the first Hall-effect sensor.

2. The apparatus of claim 1, comprising:
a processor circuit, electrically coupled to the magnetic field detector, the processor capable of selecting an operating mode of the implantable device based on the magnetic field detected by the magnetic field detector.

3. The apparatus of claim 2, wherein the processor is configured to select a magnetic resonance (MR) compatible therapy mode when an MR magnetic field is detected.

4. The apparatus of claim 1, further comprising a second Hall-effect sensor including third and fourth current terminals configured to provide a second current path therebetween for Hall-effect magnetic field sensing using third and fourth voltage sensing terminals located transverse to the second current path, wherein the first current path is non-parallel to the second current path.

5. The apparatus of claim 4, wherein the first current path of the first Hall-effect sensor is substantially perpendicular to the second current path of the second Hall-effect sensor.

6. The apparatus of claim 1, wherein the first permanent current barrier between the first and second current terminals of the first Hall-effect sensor comprises a counterdoped diffusion.

7. The apparatus of claim 1, wherein the first permanent current barrier between the first and second current terminals includes deep reactive ion-etched (DRIE) current barrier.

8. The apparatus of claim 1, wherein the first permanent current barrier between the first and second current terminals comprises a shallow trench isolation comprising a depth of less than 10 μm.

9. The apparatus of claim 1, wherein the first permanent current barrier between the first and second current terminals comprises a deep trench isolation comprising a depth of greater than 5.0 μm.

10. The apparatus of claim 4, wherein the magnetic field sensor comprises:
a third Hall-effect sensor including fifth and sixth current terminals configured to provide a third current path therebetween for Hall-effect magnetic field sensing using fifth and sixth voltage sensing terminals transverse to the third current path, wherein the third Hall-effect sensor includes a second permanent current barrier located between the fifth and sixth current terminals, and wherein the first current path is non-parallel to the second current path and the third current path is non-parallel to the first and second current paths.

11. The apparatus of claim 1, wherein the first permanent current barrier is located in a range between about 0.1 μm and about 1000 μm away from the first current terminal.

12. The apparatus of claim 1, wherein a depth of the first permanent current barrier is a value between about 0.1 μm and about 1000 μm.

13. The apparatus of claim 1, wherein the first permanent current barrier is configured such that the first current path includes a portion that is angled at an angle value that is between about 0.05° and about 45° in relation to a surface of the first Hall-effect sensor.

14. The apparatus of claim 1, wherein the first Hall-effect sensor and second Hall-effect sensor are part of the same integrated circuit.

15. The apparatus of claim 1, wherein the first permanent current barrier between the first and second current terminals of the first Hall-effect sensor comprises:
a counter-doped well region; and
a diffusion region, adjacent to, shallower than, and of opposite doping as the counter-doped well region.

16. A method comprising:
detecting a magnetic field using a magnetic field detector of an implantable device, wherein the detecting comprises:
producing a first current path non-parallel to the surface of an integrated circuit of the magnetic field detector caused by a first permanent current barrier distorting the first current path; and
sensing the magnetic field using a response voltage that is transverse to the first current path.

17. The method of claim 16, comprising:
selecting an operating mode of the implantable device based on the detected magnetic field, using a processor electrically coupled to implantable device.

18. The method of claim 17, comprising:
detecting that the magnetic field is a magnetic resonance (MR) magnetic field; and
selecting an MR-compatible mode of the implantable device when the MR magnetic field is detected.

19. The method of claim 16, comprising:
producing a second current path, wherein the second current path is non-parallel to the first current path caused by a second permanent current barrier distorting the second current path.

20. The method of claim 16, wherein producing the first current path comprises producing the first current path to be non-parallel to a surface of a first Hall effect sensor.
